(19) United States
(12) Patent Application Publication
(10) Pub. No.: US 2005/0211948 A1
(43) Pub. Date: Sep. 29, 2005

(54) Piezoelectric ceramic element for power generation and method

(76) Inventor: Michio Tsujiura, Shizuoka (JP)

Correspondence Address: ANDERSON, KILL & OLICK, P.C., 1251 AVENUE OF THE AMERICAS, NEW YORK,, NY, 10020-1182, US

(21) Appl. No.: 10/813,190

(22) Filed: Mar. 29, 2004

(51) Int. Cl. H01L 41/04

(52) U.S. Cl. 252/62.9 R; 252/62.9 PZ; 310/311; 310/367; 501/95.1; 501/95.2

(57) ABSTRACT

A ceramic structure for forming a piezoelectric ceramic element for power generation and method formed by blending a mixture of ceramic particles and heat resistant fibers together with the heat resistant fibers possessing a sintering temperature and tensile strength higher than that possessed by the ceramic particles in the composite. The fibers added to the composite have a higher melting point than the sintering temperature of the ceramic powder particles resulting in improved crack resistance.

### TECHNICAL FIELD

The present invention relates to a piezoelectric ceramic composite material for power generation and method.

### RELATED ART

Ceramic elements of conventional technology are made by mixing a variety of metallic particle powders and sintering the powders into a desired shape resulting in a brittle structure. It has been observed that when such ceramic elements are used to form piezoelectric ceramic elements for power generation the brittle characteristic of such material increases the susceptibility to bending stresses which limit their utility for this application.

The composition and method of the present invention enhances the resistance of the composition of ceramic elements to mechanical bending stresses.

### SUMMARY OF THE INVENTION

The present invention is directed to a piezoelectric ceramic particle composition comprising a mixture of thin ceramic particles and high temperature resistance fibers having a sintering temperature and tensile strength higher than that possessed by the ceramic material particles in the mixture thereby enhancing the resistance of the ceramic particle composition to bending stresses.

The present invention is also directed to a method of forming a composition of ceramic particles resistant to bending stresses comprising the steps of mixing thin ceramic particles with high temperature resistance fibers with the high temperature resistance fibers having a sintering temperature and tensile strength higher than that possessed by the ceramic material particles in the mixture.

### BRIEF DESCRIPTION OF THE DRAWING

FIG. 1 is a cross sectional view of the ceramic particle composition of the present invention.

### DETAILED DESCRIPTION OF THE INVENTION

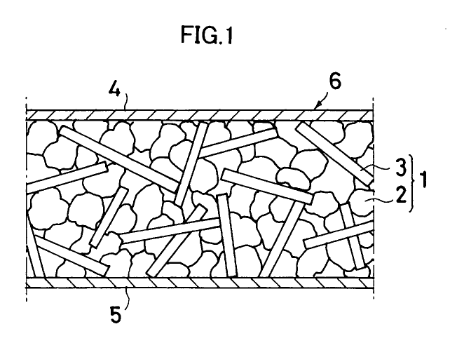

FIG. 1 is an enlarged view of a simplified configuration of the polarized piezoelectric thin film composite ceramic structure 6 of the present invention in cross-section. The preferred method of forming the structure 6 in accordance with the present invention comprises the steps of: adding high temperature resistance fibers 3 to a powder composition of ceramic particles 2; mixing the fibers 3 and ceramic particles 2 to form a ceramic composite 1 with the fibers uniformly distributed throughout the ceramic composite 1, compressing the ceramic composite 1 into a thin film, drying the thin film and sintering at a temperature below the melting point of the ceramic particles 2 into a ceramic composite structure. The preferred sintering temperature is between 1150 and 1350 degrees Centigrade. The ceramic composite 1 can be compressed into a thin film by passing the ceramic composite 1 under a doctor knife or the like. Moreover, the fibers may alone act as a binder to the ceramic particles in the powder composition or an additional binder can be added to form a slurry.

The ceramic particles may be composed of any ceramic material such as for example, lead titanate and lead zirconate, and the like. The fibers to be added to the ceramic particles may be of any material composition provided they possess a sintering temperature and tensile strength higher than that possessed by the ceramic particles in the composite mixture. The fibers are preferably ceramic fibers which have insulating properties. The geometry and length of the fibers is however important relative to the size of the ceramic particles. The fibers should preferably be of a length equal to between 3 to 10 times the average diameter of the ceramic powdered particles into which they are mixed. Ceramic fibers are preferred and they have in general two fundamental geometries. One is a simple fiber structure having an angle of 0 (zero) between the direction of a molecular chain axis and the direction of a fiber axis. Another is a spiral fiber structure in which the direction of a molecular chain axis and the direction of a fiber axis cross each other spirally. Both of these geometries may be used for the fibers of the present invention. In forming the composite it is preferable that ceramic fibers be mixed with the powdered ceramic particles in a volumetric ratio of ceramic fibers to ceramic particles of 3% to 20%.

To polarize the ceramic composite 1 an electrode coating 4, 5 is screen printed on opposite sides of the ceramic composite 1 or hot stamped utilizing a good conductive ink such as silver paste or the like. The electrode coating 4,5 is formed at corresponding points on the upper and the lower surfaces of the ceramic composite 1. The electrode 4 on the upper surface is referred to as positive electrode and the electrode 5 on the lower surface as negative electrode. The electrodes 4 and 5 are preferably of the same size and shape.

The quality and shape of the fibers 3 which are uniformly blended into the ceramic powder particles 2 should not age or deform at the high temperature used for sintering.

The uniformly blended fibers 3 function as a binder for the ceramic particles 2, to prevent the sintered ceramic composite structure 1 from cracking. The sintered ceramic composite structure 1 therefore does not break even though mechanical bending stresses are applied thereto.

The piezoelectric thin film composite ceramic structure 6 containing electrodes 4,5 which are screen printed or hot stamped and polarized form an electric insulator. As mechanical stress is applied to the piezoelectric ceramic body 6, electrical energy is generated in the entire structure, which is referred to as “total energy”. Some of the total electric energy is generated inside the structure of the piezoelectric composite ceramic body 6 which will not reach the electrodes because of the presence of the fibers acting as insulating particles in the structure of piezoelectric ceramic 6, being left inside thereof. This mitigates electric energy yield.

Blending in additional conductive fibers composed of, for example carbon. into the piezoelectric ceramic also makes the conduction of energy from within the ceramic structure easier. Although the blending of good conductive fibers into the composite ceramic may mitigate the voltage induced polarization efficiency, the advantage of leaving internal electric energy overweighs the disadvantage.

1. A ceramic structure for forming a piezoelectric ceramic element for power generation comprising a composite formed of a blended mixture of ceramic particles and heat resistant fibers with said heat resistant fibers possessing a sintering temperature and tensile strength higher than that possessed by the ceramic particles in the composite.

2. A ceramic structure for forming a piezoelectric ceramic element for power generation as defined in claim 1 wherein said fibers are ceramic fibers having insulating properties.

3. A ceramic structure for forming a piezoelectric ceramic element for power generation as defined in claim 1 wherein the ceramic particles are in powdered form and the fibers are of a length equal to between 3 to 10 times the average diameter of the ceramic powdered particles.

4. A ceramic structure for forming a piezoelectric ceramic element for power generation as defined in claim 1 wherein the ceramic fibers are intermixed with the ceramic particles in a volumetric ratio of ceramic fibers to ceramic particles of 3% to 20%.

5. A ceramic structure for forming a piezoelectric ceramic element for power generation as defined in claim 3 wherein the ceramic fibers are intermixed with the ceramic particles in a volumetric ratio of ceramic fibers to ceramic particles of 3% to 20%.

6. A ceramic structure for forming a piezoelectric ceramic element for power generation as defined in claim 3 wherein the heat resistant fibers function as insulators.

7. A ceramic structure for forming a piezoelectric ceramic element for power generation as defined in claim 6 further comprising additional fibers which are conductive fibers with the fibers intermixed to efficiently yield electrical energy inside said ceramic structure as mechanical stresses induce distortion of the piezoelectric ceramic element.

8. A ceramic structure for forming a piezoelectric ceramic element for power generation as defined in claim 7 wherein said conductive fibers are composed of carbon.

9. A method for forming a piezoelectric ceramic element for power generation comprising the steps of forming a blended mixture of ceramic particles and heat resistant fibers with the heat resistant fibers possessing a sintering temperature and tensile strength higher than that possessed by the ceramic particles in the composite.
